(19) United States
(12) Patent Application Publication
(10) Pub. No.: US 2013/0277991 A1
(43) Pub. Date: Oct. 24, 2013

(54) STEPLESS ADJUSTABLE MOBILE ELECTRONIC DEVICE HOLDER

(71) Applicant: FU-CHI WU, NORTHRIDGE, CA (US)

(72) Inventor: FU-CHI WU, NORTHRIDGE, CA (US)

(21) Appl. No.: 13/450,543

(22) Filed: Apr. 19, 2012

(51) Int. Cl. H05K 7/00; A45F 5/00

(52) U.S. Cl. 294/25; 224/191

(57) ABSTRACT

A stepless adjustable mobile electronic device holder includes a holder body configured for holding a smart phone or tablet PC, and fastening straps affixed to the back side of the holder body, each fastening strap having a buckle ring disposed at one end thereof and a hook and loop pad disposed at an opposite end thereof and insertable with the respective end through the buckle ring for joining the two ends of the respective fastening strap to secure the holder body to one or more fingers of a person.

### BACKGROUND OF THE INVENTION

1. Field of the Invention

The present invention relates to mobile electronic device holder configured for holding a mobile electronic device, for example, smart phone or tablet PC, and more particularly, to a stepless adjustable mobile electronic device holder, which comprises a holder body configured for holding a smart phone or tablet PC, and fastening straps affixed to the back side of the holder body and having a buckle ring and a hook and loop pad disposed at opposite ends thereof for fastening the holder body to one or more fingers of the user for enabling the user to take pictures or to record video steadily with one single hand.

2. Description of the Related Art

Following fast development of electronic and communication technologies and rise of living standards, many people have a smart phone and a tablet PC. In addition to the basic function for dialing a telephone number and sending a message, a smart phone can be used to take pictures, to record videos, to connect to the Internet for data searching, to play music and video games, and to watch videos. The camera of a smart phone provides sharp, high-definition imagery. However, the quality of pictures and videos obtained by a smart phone is poor due to that when using a smart phone, one shall have to hold the body of the smart phone with one hand and to touch the touch-sensitive control zone of the touch screen of the smart phone with the other hand, and rotation is naturally produced subject to the thrust of the finger touching the touch-sensitive control zone against user's instinct to keep the body in balance, causing vibration or biasing of the smart phone to affect the sharpness quality of photo shoot. Further, because a smart phone has a small size and smooth surface and edges, it is difficult to take a picture or recording a video with one single hand.

Further, when using a smart phone or tablet PC, the user may need to hold the smart phone or tablet PC with one hand and touching the touch-sensitive control zone of the touch screen with the other hand, making the operation difficult. When a tablet PC is horizontally placed on a table or flat surface, the user cannot view the screen of the tablet PC comfortably. Further, when one holds a tablet PC and stands on the ground or is walking, one cannot use the tablet PC conveniently. Further, when sitting on the driver's seat in a cart, the driver cannot use a smart phone or tablet PC to watch on-line videos, to play on-line video games, or to drive a GPS navigation system comfortably. Further, a car may be equipped with a GPS navigation system and a video system for searching on-line data, watching on-line videos or playing on-line video game. However, an automobile video system is not detachable for mobile application. Further, the definition of an automobile video system is lower than an advanced tablet PC. Therefore, it is desirable to provide a smart phone/tablet PC holder, which enables a smart phone or tablet PC to be detachably secured to the hand or a person or the steering wheel of a car, or adjustably supported on a table or flat surface in a tilted position convenient for applications.

### SUMMARY OF THE INVENTION

The present invention has been accomplished under the circumstances in view. It is the main object of the present invention to provide a stepless adjustable mobile electronic device holder, which comprises a holder body configured for holding a mobile electronic device, for example, smart phone, and at least one fastening strap affixed to the back side of the holder body. Each fastening strap comprises a buckle ring and a hook and loop pad respectively disposed two opposite ends thereof and adapted for joining the two opposite ends to secure the holder body to a finger of a person. By means of the hook and loop pad, each fastening strap can be fastened to one or more fingers of the user so that the user can use one single finger of the hand holding the holder body to touch the touch-sensitive control zone of the touch screen of the smart phone in the holder body in taking a picture or recording images. Thus, when the user operates the smart phone to take pictures or to record video, the smart phone will not fall from the user's hand.

Further, by means of the hook and loop pad, each fastening strap can be arranged in the form of a loop for supporting the holder body and a smart phone/tablet PC on a flat surface in a tiled position in a horizontal or vertical condition subject to the desired view angle.

Further, by means of the at least one fastening strap, the stepless adjustable mobile electronic device holder can be fastenable to a shoulder strap of a bag or a waist belt.

Further, the user can fasten each fastening strap to a steering wheel of a car to hold a smart phone or tablet PC in the holder body so that the driver can use the smart phone or tablet PC to search data, to watch on-line videos or to play on-line video games in the car, or to drive a GPS navigation system.

### BRIEF DESCRIPTION OF THE DRAWING

FIG. 1 is an exploded view of a stepless adjustable mobile electronic device holder in accordance with a first embodiment of the present invention.

FIG. 2 is an exploded view of the stepless adjustable mobile electronic device holder and a smart phone in accordance with the present invention.

FIG. 3 is a schematic drawing of the present invention, illustrating the stepless adjustable mobile electronic device holder fastened to a finger of a user to hold a smart phone.

FIG. 4 illustrates the fastening straps of the stepless adjustable mobile electronic device holder directly affixed to a back cover of a smart phone in accordance with the present invention.

FIG. 5 is a schematic applied view of the present invention, illustrating the stepless adjustable mobile electronic device holder fastened to a shoulder strap of a bag.

FIG. 6 another schematic applied view of the present invention, illustrating the stepless adjustable mobile electronic device holder fastened to a waist belt.

FIG. 7 illustrates the fastening straps of the stepless adjustable mobile electronic device holder respectively arranged in a loop and a smart phone held in the holder body of the stepless adjustable mobile electronic device holder and supported in a tilted position in a vertical condition.

FIG. 8 is an exploded view of the stepless adjustable mobile electronic device holder and a tablet PC in accordance with the present invention.

FIG. 9 illustrates the fastening straps of the stepless adjustable mobile electronic device holder respectively arranged in a loop and a smart phone held in the holder body of the stepless adjustable mobile electronic device holder and supported in a tilted position in a horizontal condition.

FIG. 10 illustrates one fastening strap of the stepless adjustable mobile electronic device holder fastened to a support and a tablet PC held in the holder body of the stepless adjustable mobile electronic device holder and supported in a tilted position.

FIG. 11 illustrates one fastening strap of the stepless adjustable mobile electronic device holder fastened to a support and a tablet PC held in the holder body of the stepless adjustable mobile electronic device holder and supported in another tilted position.

FIG. 12 illustrates one fastening strap of the stepless adjustable mobile electronic device holder fastened to another support and a tablet PC held in the holder body of the stepless adjustable mobile electronic device holder and supported in a tilted position.

### DETAILED DESCRIPTION OF THE PREFERRED EMBODIMENT

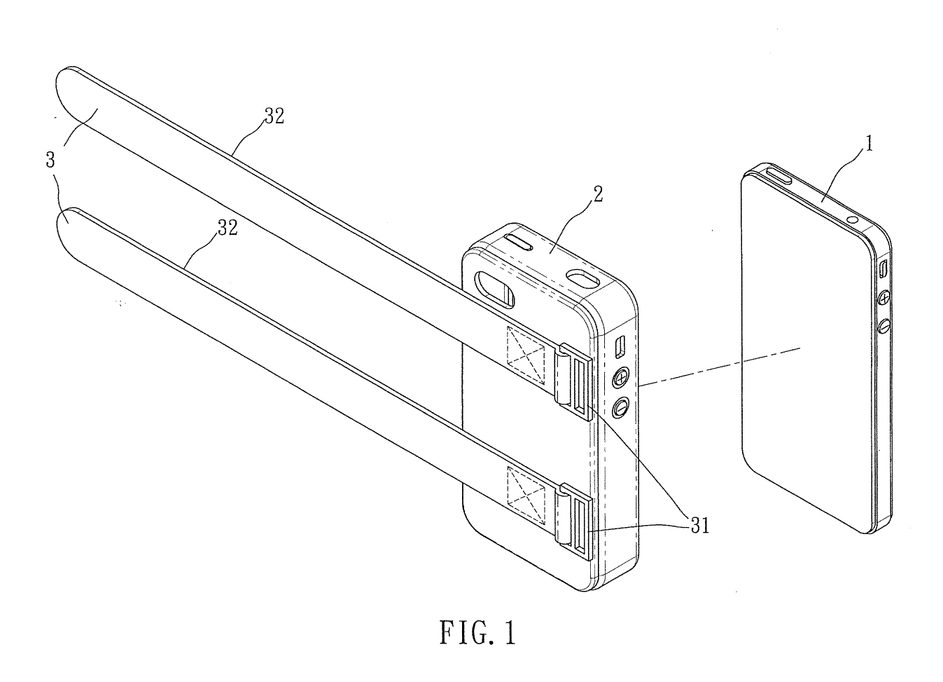

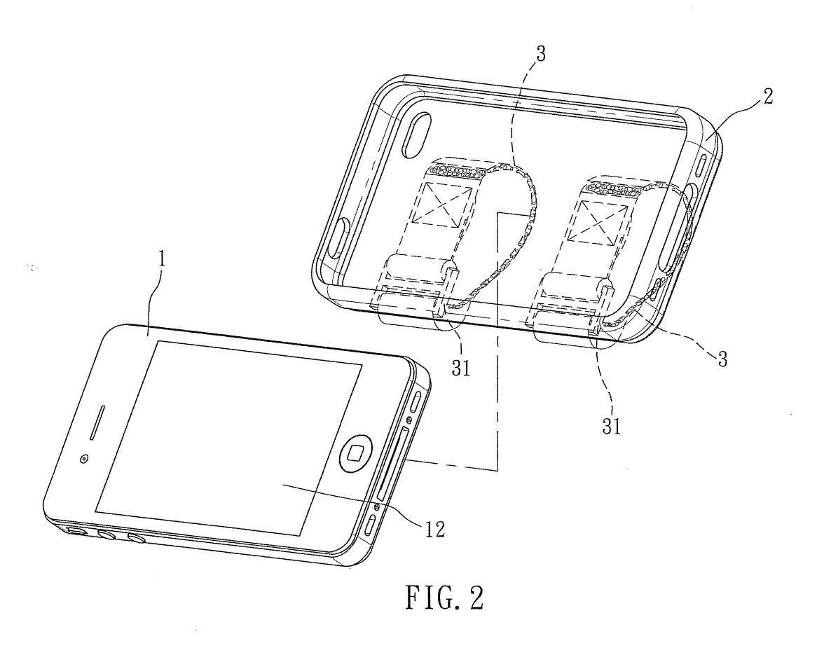

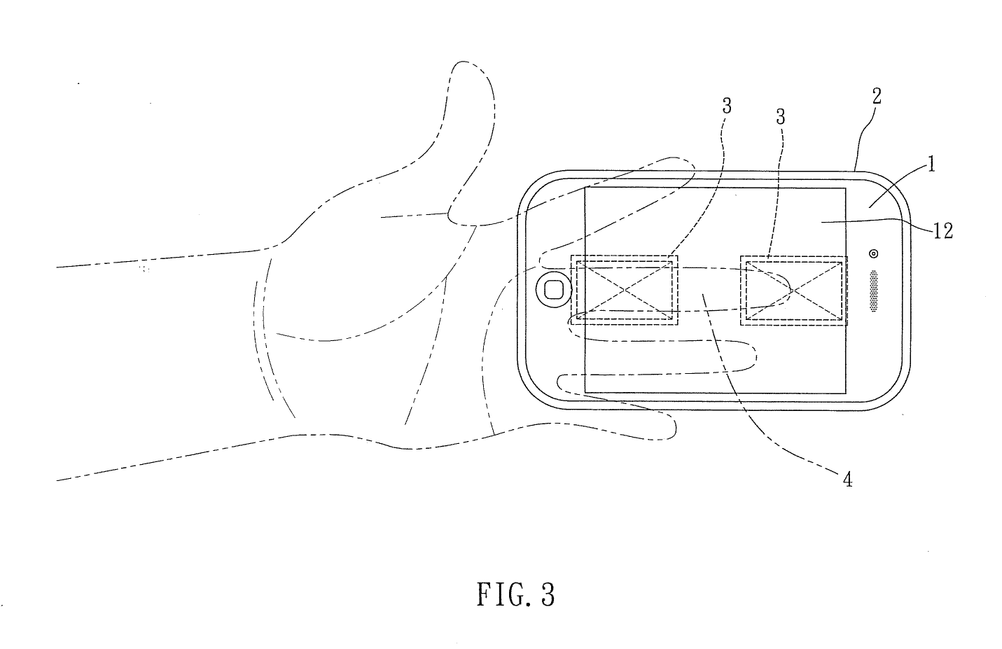

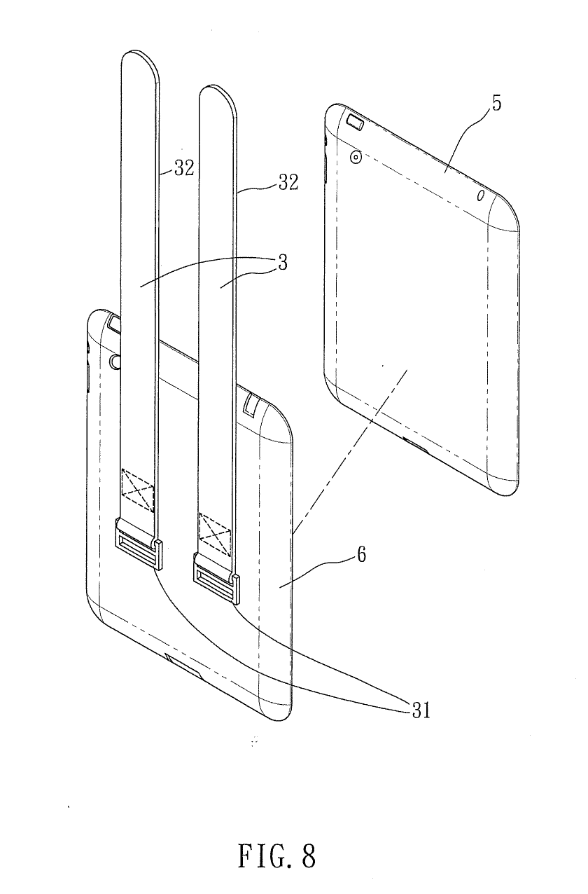

Referring to FIGS. 1, 2 and 8, a stepless adjustable mobile electronic device PC holder in accordance with the present invention is shown. The stepless adjustable mobile electronic device holder comprises a holder body 2 or 6 for holding a smart phone 1 or tablet PC 5, at least one, for example, two fastening straps 3 affixed to the back side of the holder body 2 or 6. The fastening straps 3 can be made having a respective buckle ring 31 at one end thereof. Alternatively, the fastening straps 3 can be made without the buckle ring 31. The other end of each fastening strap 3 that is provided a buckle ring can be inserted through the associating buckle ring 31. Further, the other end of each fastening strap 3 is provided with a hook and loop pad 32 or buckle ring positioning means. By means of the hook and loop pad 32 or buckle ring positioning means, the fastening straps 3 can be fastened to one or more fingers 4 of the user (see FIG. 3), i.e., the hook and loop pad 32 or buckle ring positioning means can join the ends of each fastening strap 3 to secure the holder body 2 or 6 positively to one or more fingers 4 of the user. At this time, the user can use one single finger of the hand holding the holder body 2 to touch the touch-sensitive control zone of the touch screen 12 of the smart phone 1 in the holder body 2 in taking a picture, and the smart phone 1 is positively held in position without vibration. Thus, when the user operates the smart phone 1 to take a picture or to record images, the smart phone 1 will not fall from the user's hand.

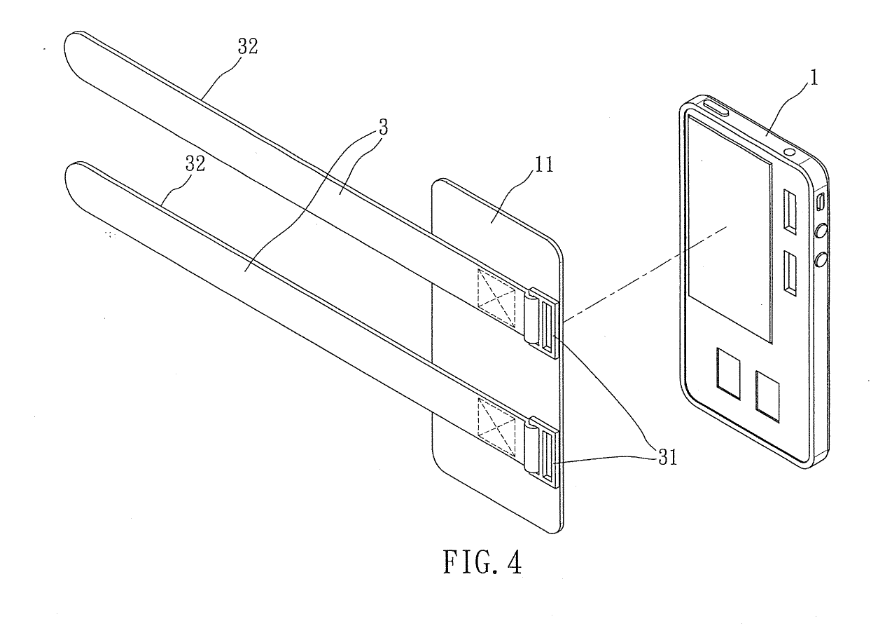

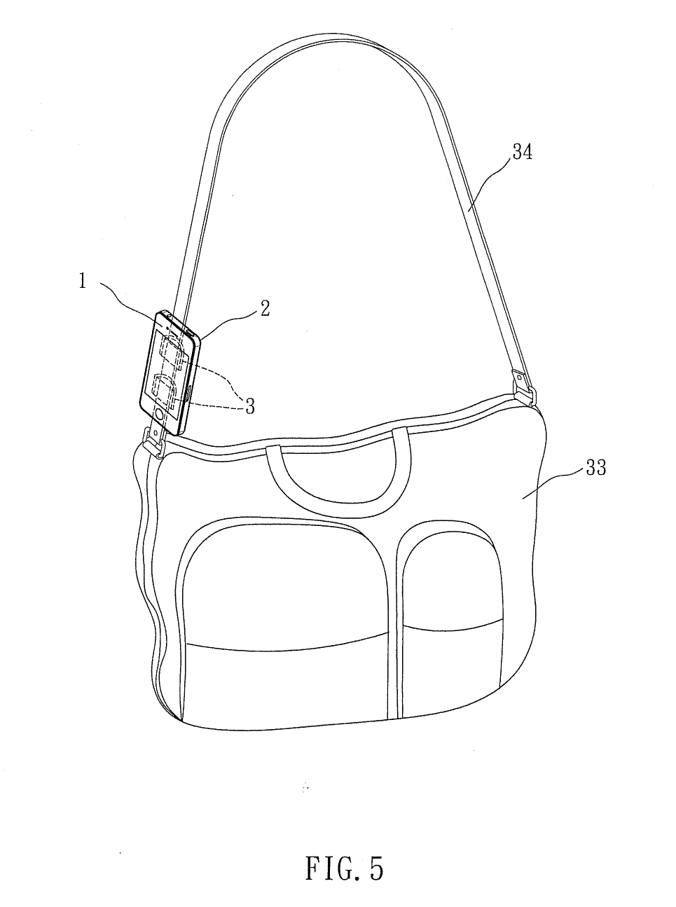

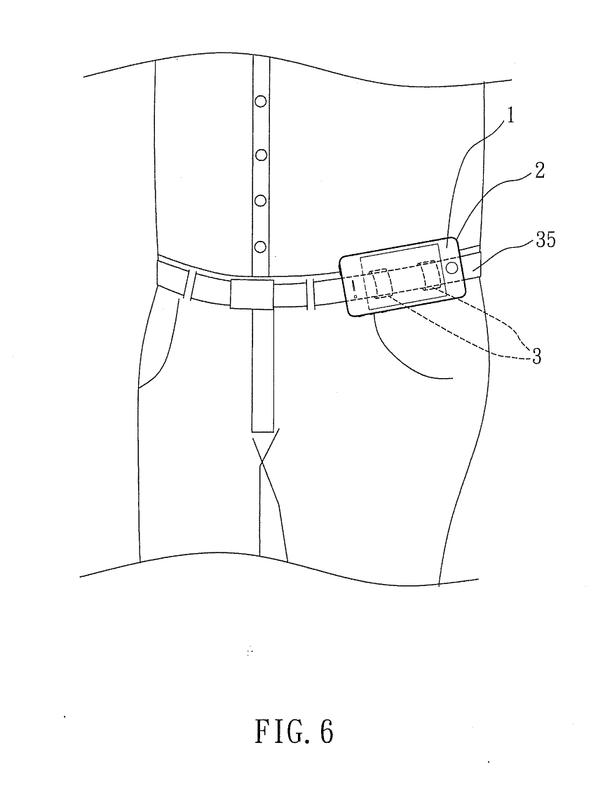

Further, the user can use the holder body 2 and the fastening straps 3 to fasten the smart phone 1 to the shoulder strap 34 of his (her) bag 33 (see FIG. 5) or his (her) waist belt 35 (see FIG. 6), avoiding missing an important phone call due to a low ringing sound if the smart phone is received in a pocket or bag. Further, the fastening straps 3 can be directly affixed to the back cover 11 of a smart phone 1 (see FIG. 4).

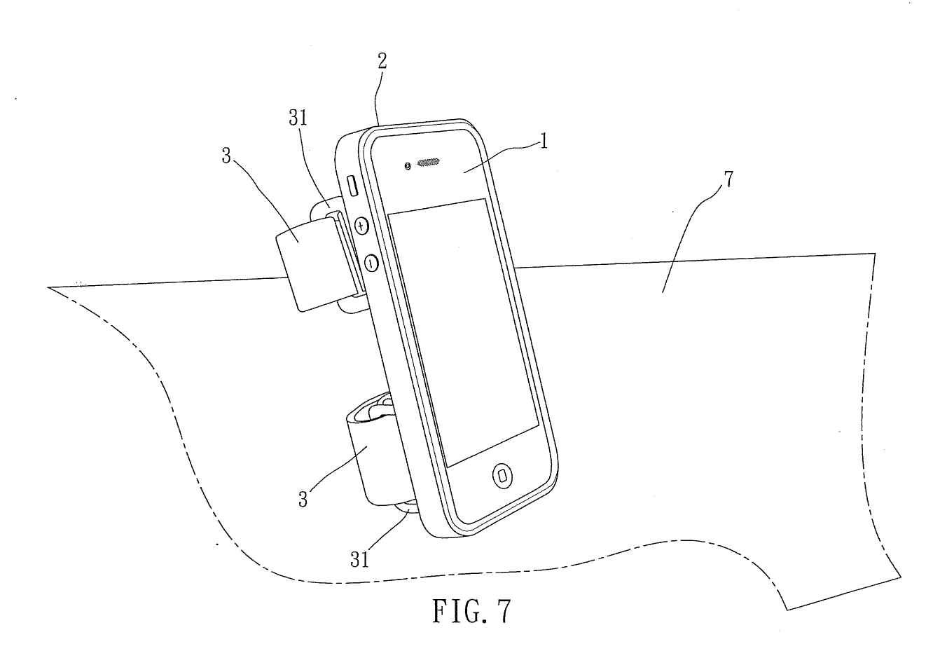

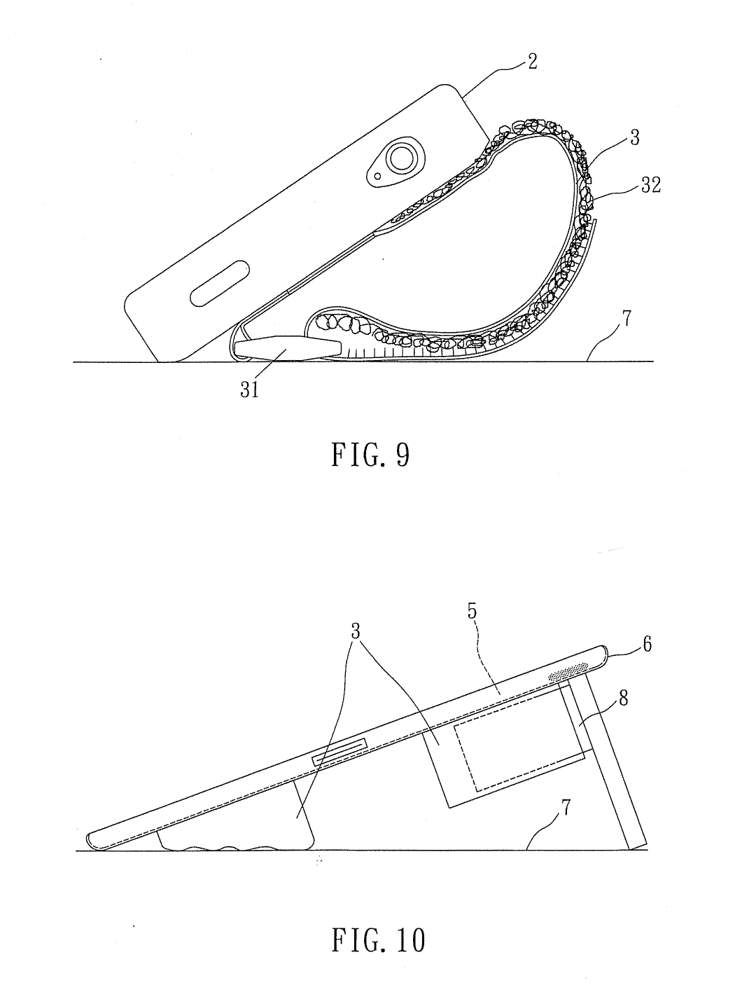

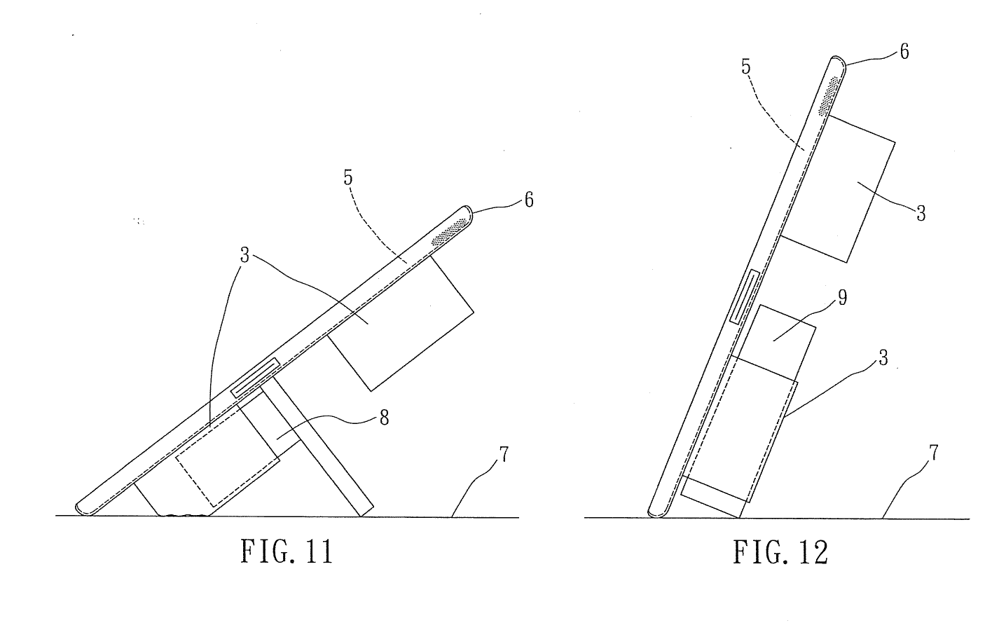

Further, by means of the hook and loop pad 32 or buckle ring positioning means to join the ends of each fastening strap 3, each fastening strap 3 is secured in the form of a loop. At this time, the user can adjust the size of the loop to directly support the holder body 2 and the smart phone 1 on the top surface of a table 7 in a tilted position in a vertical condition (see FIG. 7) or horizontal position (see FIG. 9). Further, one fastening strap 3 can be fastened to a hard support 8 or 9, enabling the hard support 8 or 9 to support the holder body 6 and a tablet PC 5 on the top surface of a table 7 in a tilted position in a vertical or horizontal position (see FIGS. 10, 11 and 12).

Further, the fastening straps 3 can be made of an elastic material. When the fastening straps 3 are respectively secured in the form of a loop, the user can press the loop to adjust its shape, thereby adjusting the tilt angle of the holder body 2 or 6 and the smart phone 1 or tablet PC 5 in a stepless manner.

In conclusion, the invention provides a stepless adjustable mobile electronic device holder, which enables the user to hold a smart phone steadily for taking a picture or recording images, or to rest a smart phone or tablet PC on a flat surface in a tilted position in a horizontal or vertical condition subject to the desired view angle.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A stepless adjustable mobile electronic device holder, comprising:
a holder body configured for holding a mobile electronic device; and
at least one fastening strap affixed to a back side of said holder body, each said fastening strap comprising opposing first end and second, and a hook and loop pad disposed at one of said first end and said second end and adapted for joining said first end and said second end to secure said holder body to one or more fingers of a person.

2. The stepless adjustable mobile electronic device holder as claimed in claim 1, wherein said at least one fastening strap is fastenable to a shoulder strap of a bag by means of said buckle ring and said hook and loop pad.

3. The stepless adjustable mobile electronic device holder as claimed in claim 1, wherein said at least one fastening strap is directly affixed to a back cover of a smart phone.

4. The stepless adjustable mobile electronic device holder as claimed in claim 1, wherein the second end of each said fastening strap is insertable through the associating buckle ring for enabling the associating hook and loop pad to secure the respective fastening strap in the form of a loop.

5. The stepless adjustable mobile electronic device holder as claimed in claim 1, wherein said holder body is configured to hold a smart phone.

6. The stepless adjustable mobile electronic device holder as claimed in claim 1, wherein said holder body is configured to hold a tablet PC.

7. The stepless adjustable mobile electronic device holder as claimed in claim 6, further comprising a support member fastenable to said at least one fastening strap and adapted for supporting said holder body on a flat surface in a tilted position.

8. The stepless adjustable mobile electronic device holder as claimed in claim 7, wherein said support member is a daily consumer product.

9. The stepless adjustable mobile electronic device holder as claimed in claim 1, wherein each said fastening strap further comprises a buckle ring disposed at said first end; said hook and loop pad is disposed at said second end and insertable with said second end through said buckle ring and adapted for joining said first end and said second end to secure said holder body to one or more fingers of a person.
